(19) United States
(12) Patent Application Publication
(10) Pub. No.: US 2018/0191061 A1
(43) Pub. Date: Jul. 5, 2018

(54) PROCESS TECHNOLOGY FOR EMBEDDED HORN STRUCTURES WITH PRINTED CIRCUIT BOARDS

(71) Applicant: Intel Corporation, Santa Clara, CA (US)

(72) Inventors: Arvind Sundaram, Bangalore (IN); Vikas Mishra, Bangalore (IN); Ramaswamy Parthasarathy, Bangalore (IN); Sandesh G K., Bangalore (IN)

(21) Appl. No.: 15/474,541

(22) Filed: Mar. 30, 2017

Related U.S. Application Data
(60) Provisional application No. 62/442,683, filed on Jan. 5, 2017.

(51) Int. Cl. H01Q 1/38; H05K 1/02; H05K 3/46; H05K 3/18; H01Q 13/02

(52) U.S. Cl. CPC H01Q 1/38; H05K 1/0242; H01Q 13/0275; H05K 3/188; H05K 3/4611; H05K 3/4697

(57) ABSTRACT

An apparatus comprises a multi-layer printed circuit board (PCB) including a plurality of board layers arranged between a top surface of the PCB and a bottom surface of the PCB; and a surface wave launcher for a single-wire transmission line arranged below the top surface of the PCB and above the bottom surface of the PCB.

### CLAIM OF PRIORITY

This application claims the benefit of priority to U.S. Provisional Application Ser. No. 62/442,683, filed Jan. 5, 2017, which is incorporated herein by reference in its entirety.

### TECHNICAL FIELD

Embodiments pertain to high speed signal communication using single-wire transmission lines and in particular to methods and apparatus for launching surface waves onto single-wire transmission lines.

### BACKGROUND

As more electronic devices become interconnected and users consume more data, the demand on electronic system performance continues to increase. The increased demand for performance and capacity has led system designers to look for ways to increase data rates and maintain or increase the interconnect distance. One approach to interconnecting electronic devices is to use transmission lines such as coaxial transmission lines as high speed links. Conventional transmission lines have adequate performance until transmission rates exceed ten gigabits per second (10 Gbps). Beyond this rate, losses in the transmission lines become excessive. To avoid the losses, reduced transmission rates are used with multiple or parallel lanes of transmission lines. Cross talk between transmission line lanes also becomes a problem at high transmission rates. To mitigate crosstalk, differential signals are transmit over the transmission lines.

Additionally, multiple lanes can complicate system interconnect quickly as designers try to achieve higher rates. Additionally, even at rates below 10 Gbps, the high rates limit the maximum distance signal can travel and limit the length of the transmission lines. The present inventors have recognized a need for improvements in the interconnection between electronic devices.

### BRIEF DESCRIPTION OF THE DRAWINGS

FIG. 1 is an illustration of an exploded view of an embodiment of a multi-layer printed circuit board, in accordance with some embodiments;

FIG. 2 is an illustration of a launcher die, in accordance with some embodiments;

FIG. 3 is an illustration of a laminated stack of board layers, in accordance with some embodiments;

FIG. 4 is another illustration of a laminated stack of board layers, in accordance with some embodiments;

FIG. 5 is an illustration of a side view of a surface wave launcher, in accordance with some embodiments;

FIG. 6 is an illustration of a system level diagram, in accordance with some embodiments; and

FIG. 7 is a flow diagram of a method of making a surface wave launcher, in accordance with some embodiments.

### DETAILED DESCRIPTION

The following description and the drawings sufficiently illustrate specific embodiments to enable those skilled in the art to practice them. Other embodiments may incorporate structural, logical, electrical process, and other changes. Portions and features of some embodiments may be included in, or substituted for, those of other embodiments. Embodiments set forth in the claims encompass all available equivalents of those claims.

Conventional transmission lines may not meet the emerging requirements for electronic systems. Single-wire communication (SWC) is an alternative to conventional transmission lines. A single-wire transmission line communicates data over a single wire or line without a second ground or return line. SWC has the potential to enable communication at higher rates with low loss up to 40 Gbps. However, there are presently a lot of impracticalities involved with implementing SWC.

In SWC, electromagnetic surface waves are created or launched on the single-wire line. A circuit component called a surface wave launcher, or launcher, is needed for single-wire transmission to be effective. Launchers are used to translate electromagnetic signals into the electromagnetic surface waves. Launchers are metallic devices that need to be small in size and can include multiple parts. Machining required to create such devices can be difficult and expensive. Also, launchers can have a parabolic shape and may have dimensions on the order of millimeters. Their shape and small size make them difficult to incorporate into a pick and place process for high volume manufacturing.

A better approach is to embed the launcher into a printed circuit board (PCB) as part of the PCB manufacturing process. An embedded launcher can provide good coupling to the single-wire transmission line, eliminates the need for complicated machining, and is scalable for high volume manufacturing.

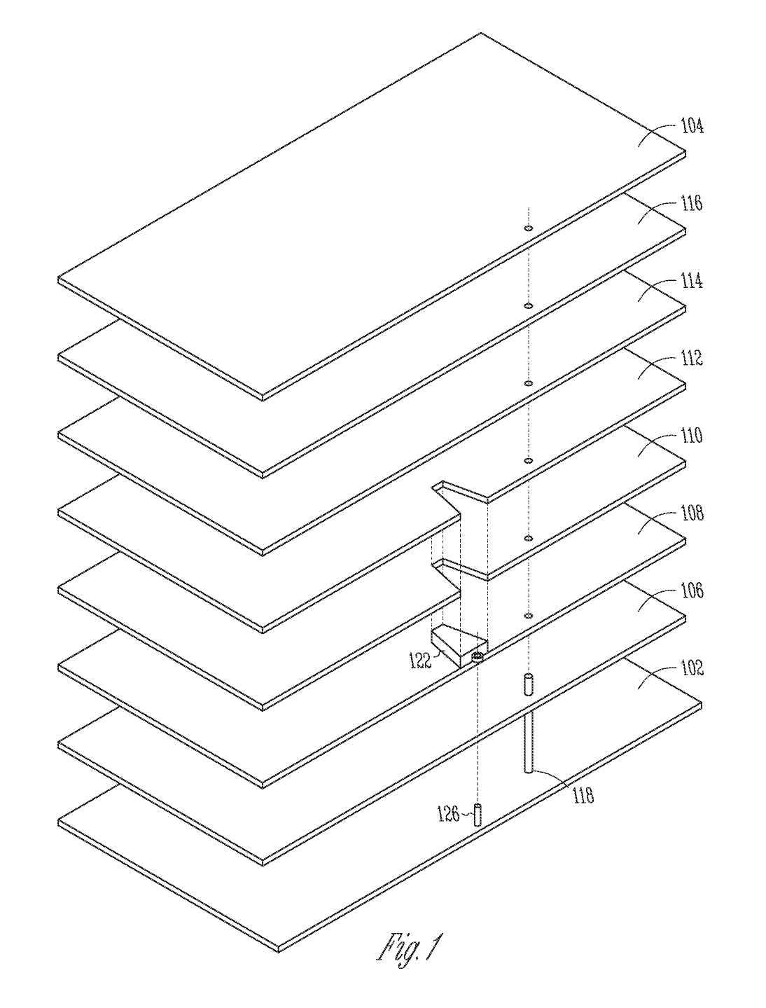

FIG. 1 is an illustration of an exploded view of an embodiment of a multi-layer PCB. The Figure shows a bottom metal (e.g., steel) plate 102 and a top metal plate 104 that are used in forming the PCB, and six board layers that are stacked and laminated together to form the PCB. In certain embodiments, the PCB is formed using 2.5D technology. To build up the PCB, a bottom board layer 106 is placed on the bottom metal plate 102. The bottom metal plate 102 includes a guide structure (e.g., guide pin 118) to receive the guide holes 120 formed in the board layers for alignment of the board layers. Four intermediate board layers (108, 110, 112, 114) are then stacked on the bottom board layer 106, followed by a top board layer 116. The number of boards is just an example. The PCB may include three or more board layers. In some embodiments the PCB includes many more than six board layers, such as 30-40 board layers or panels. The board layers may be made of prepeg (e.g., a matrix material such as epoxy pre-impregnated with fibers of a composite material) and copper. Copper traces may be pre-etched or otherwise formed on the board layers.

The launcher is formed on the edge of the PCB in the layers of the PCB. Intermediate board layers 110 and 112 include cutaways or notches that will form the sidewalls of the launcher when the layers are stacked together. The bottom of the launcher will be formed on the top surface of intermediate layer 108 and the top of the launcher will be formed on the bottom surface of intermediate layer 114. The top surface of layer 108 shows a manufacturing launcher die 122 or form disposed on the board layer. Among other functions, the launcher die can assist in guiding boarding layers 110 and 112 over board layer 108. The launcher die is eventually removed leaving a cavity in the PCB that will be used to form the actual launcher.

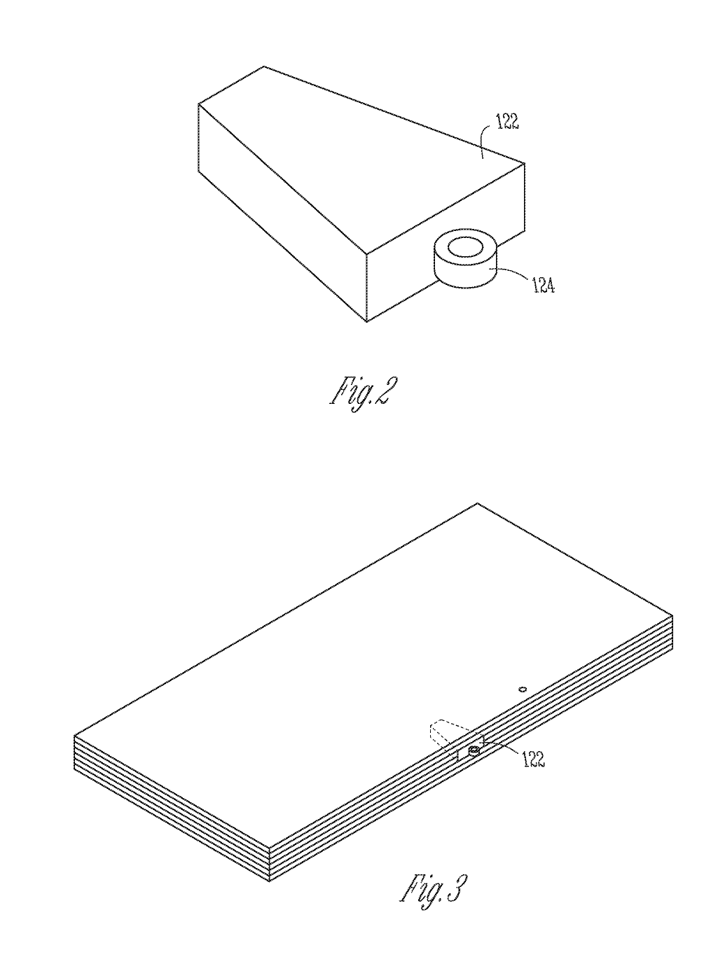

FIG. 2 is an illustration of the launcher die 122. The launcher die is prefabricated and may be precision machined to have the contours desired in the launcher that is eventually formed. The launcher die 122 includes a wide end and a narrow end opposite the wide end. The narrow end faces inward to the PCB and the wide end is arranged at the edge or near the edge of the PCB. The wide end of the launcher die can include a guide structure (e.g., a loop or ring 124). As shown in FIG. 1, the loop or ring 124 can be guided over a registration pin 126 on the bottom metal plate 102 when placed on board layer 108. The launcher die 122 can be coated with a lubricant to facilitate removal. In some embodiments, the launcher die is coated with a conductive powder such as graphite powder. The graphite powder acts as a solid lubricant to aid in the eventual removal of the launcher die. Residue graphite powder remaining in the cavity after removal of the die can be used as an electrode in an electroplating process to coat the cavity with a layer of metal to form the launcher.

The launcher die 122 can be machine placed or placed by an operator onto board layer 108, or any intermediate board layer that is just below the one or more board layers with the cut away. The other board layers are stacked according to the PCB process. The top metal plate 104 is placed over the stack and the stack of board layers is clamped. The stack is compressed and heated (e.g., using an autoclave process) to the glass transition point (Tg) where the prepeg melts. As the prepeg melts, a closed system monitors the electrical impedance of the stack using impedance measurement test coupons. A test coupon may be included as a test area of one or more board layers. When the desired impedance is achieved, the temperature is reduced while the pressure is maintained. Excess prepeg may come out of the sides of the stack which is trimmed off the PCB assembly.

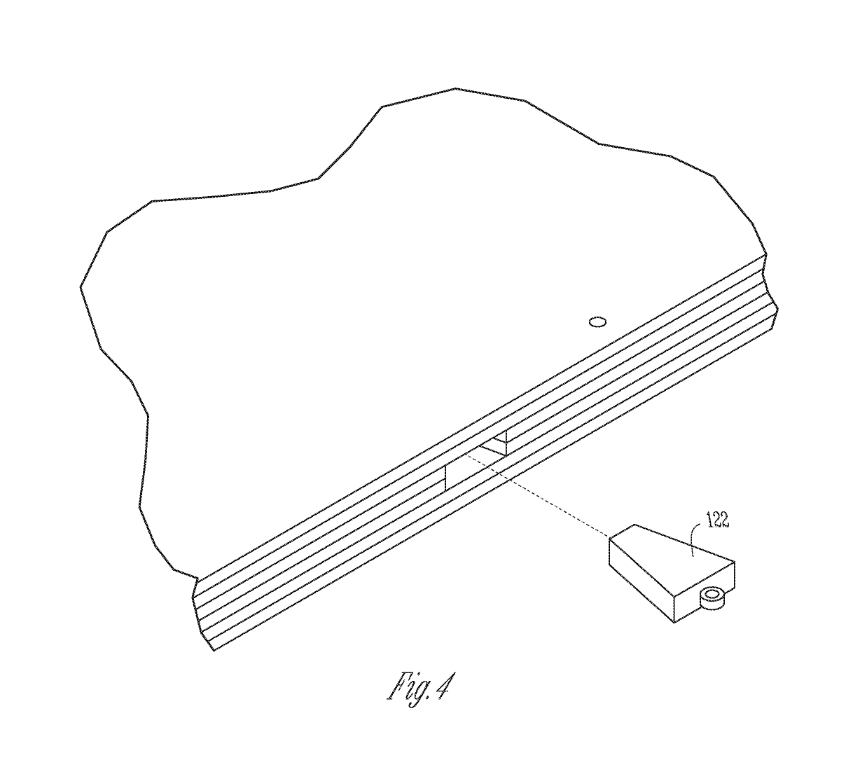

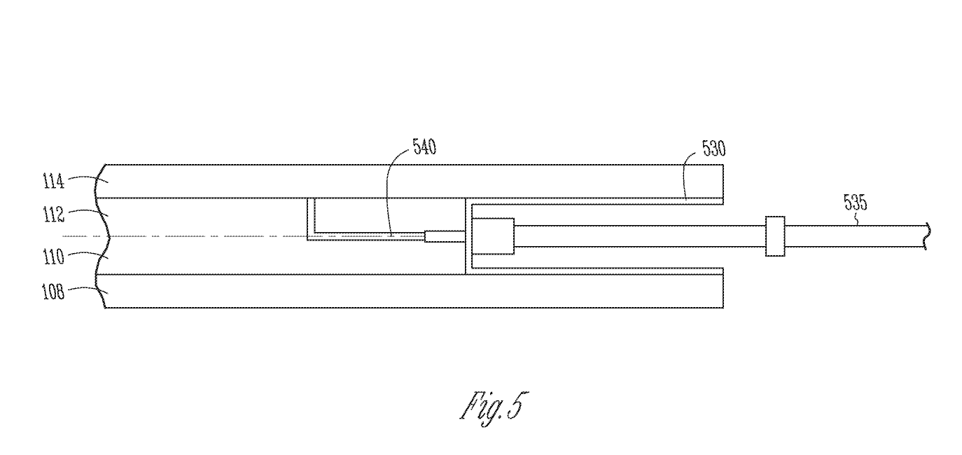

FIG. 3 is an illustration of the laminated stack of board layers after heating with the top and bottom metal plates removed and the launcher die 122 still inserted. FIG. 4 is an illustration of the multi-layer PCB with the launcher die 122 removed leaving a launcher cavity in the PCB. Because the launcher die was coated with graphite, graphite remains in the cavity. The graphite can be used as an electrode to coat the launcher cavity with copper to form the launcher.

At the center of the formed launcher on the embedded end, a keep out area is left open and not coated with the metal layer to form an opening where the board layers 110 and 112 come together. Board layers 110 and 112 are the board layers with the cutaways in the example of FIG. 1. A conductor can be etched in the board layers 110 and 112 to form the launcher feed. When an SWC cable is inserted into the launcher, a pin included in the SWC cable makes contact with the launcher feed to establish a low loss connection.

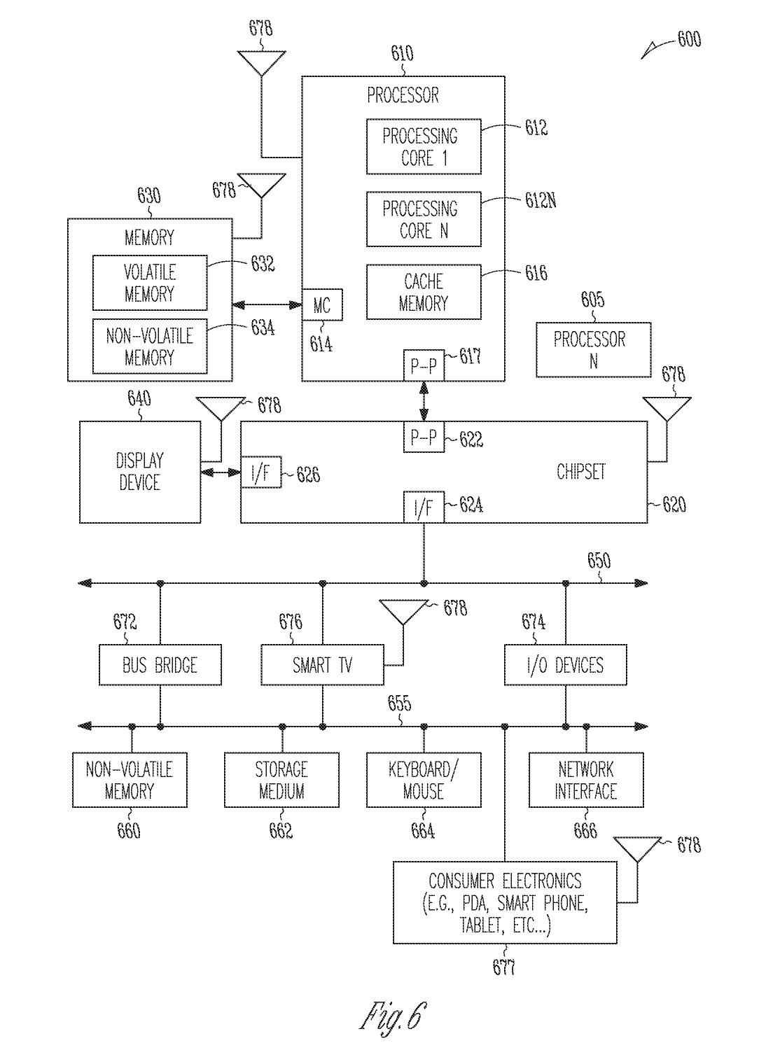

FIG. 5 is an illustration of a side view of a launcher 530 formed in board layers 108, 110, 112, and 114 according to some embodiments. An SWC cable 535 is shown in contact with a conductor feed 540 formed on one or both of board layers 110 and 112. Arranging the launcher 530 around the SWC pin and feed conductor allows a transverse electromagnetic wave (TEM) to be sent on top of the feed conductor and into the PCB, such as to a system on chip (SoC). In another example, a driver chip can drive the feed conductor to launch an electromagnetic wave onto the SWC cable.

The SWC cable and launcher form a very high speed link that can also be used to send power to the PCB. Additional launchers can be formed in the PCB, but the advantage of the launcher is that the high bandwidth can reduce the pin count needed between devices such as between SoCs. Because the prepeg melts and forms around the launcher die, the cavity will match the contours of the launcher die. Thus, if the launcher die has the bell shape of FIG. 2, the launcher will have a bell shape. The melting prepeg will match other shapes as well. The launcher die may have a parabolic shape, a horn shape, or elliptical shape, and the formed launcher will have the shape of the launcher die.

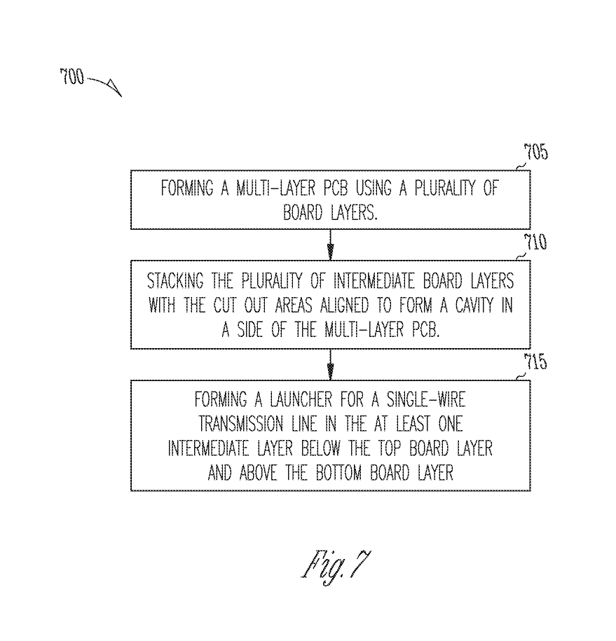

FIG. 6 illustrates a system level diagram, according to one embodiment of the invention. For instance, FIG. 6 depicts an example of an electronic device (e.g., system) that can include the SWC interconnections as described in the present disclosure. In one embodiment, system 600 includes, but is not limited to, a desktop computer, a laptop computer, a netbook, a tablet, a notebook computer, a personal digital assistant (PDA), a server, a workstation, a cellular telephone, a mobile computing device, a smart phone, an Internet appliance or any other type of computing device. In some embodiments, system 600 is a system on a chip (SOC) system. In one example two or more systems, as shown in FIG. 6 may be coupled together using one or more SWC cables as described in the present disclosure. In one specific example, one or more SWC interconnections as described in the present disclosure may implement a serial bus.

In one embodiment, processor 610 has one or more processing cores 612 and 612N, where 612N represents the Nth processor core inside processor 610 where N is a positive integer. In one embodiment, system 600 includes multiple processors including 610 and 605, where processor 605 has logic similar or identical to the logic of processor 610. In some embodiments, processing core 612 includes, but is not limited to, pre-fetch logic to fetch instructions, decode logic to decode the instructions, execution logic to execute instructions and the like. In some embodiments, processor 610 has a cache memory 616 to cache instructions and/or data for system 600. Cache memory 616 may be organized into a hierarchal structure including one or more levels of cache memory.

In some embodiments, processor 610 includes a memory controller 614, which is operable to perform functions that enable the processor 610 to access and communicate with memory 630 that includes a volatile memory 632 and/or a non-volatile memory 634. In some embodiments, processor 610 is coupled with memory 630 and chipset 620. Processor 610 may also be coupled to a wireless antenna 678 to communicate with any device configured to transmit and/or receive wireless signals. In one embodiment, the wireless antenna interface 678 operates in accordance with, but is not limited to, the IEEE 802.11 standard and its related family, Home Plug AV (HPAV), Ultra Wide Band (UWB), Bluetooth, WiMax, or any form of wireless communication protocol.

In some embodiments, volatile memory 632 includes, but is not limited to, Synchronous Dynamic Random Access Memory (SDRAM), Dynamic Random Access Memory (DRAM), RAMBUS Dynamic Random Access Memory (RDRAM), and/or any other type of random access memory device. Non-volatile memory 634 includes, but is not limited to, flash memory, phase change memory (PCM), read-only memory (ROM), electrically erasable programmable read-only memory (EEPROM), or any other type of non-volatile memory device.

Memory 630 stores information and instructions to be executed by processor 610. In one embodiment, memory 630 may also store temporary variables or other intermediate information while processor 610 is executing instructions. In the illustrated embodiment, chipset 620 connects with processor 610 via Point-to-Point (PtP or P-P) interfaces 617 and 622. Chipset 620 enables processor 610 to connect to other elements in system 600. In some embodiments of the invention, interfaces 617 and 622 operate in accordance with a PtP communication protocol such as the Intel® QuickPath Interconnect (QPI) or the like. In other embodiments, a different interconnect may be used.

In some embodiments, chipset 620 is operable to communicate with processor 610, 605N, display device 640, and other devices 672, 676, 674, 660, 662, 664, 666, 677, etc. Buses 650 and 655 may be interconnected together via a bus bridge 672. Chipset 620 connects to one or more buses 650 and 655 that interconnect various elements 674, 660, 662, 664, and 666. Chipset 620 may also be coupled to a wireless antenna 678 to communicate with any device configured to transmit and/or receive wireless signals. Chipset 620 connects to display device 640 via interface 626. Display 640 may be, for example, a liquid crystal display (LCD), a plasma display, cathode ray tube (CRT) display, or any other form of visual display device. In some embodiments of the invention, processor 610 and chipset 620 are merged into a single SOC. In one embodiment, chipset 620 couples with a non-volatile memory 660, a mass storage device(s) 662, a keyboard/mouse 664, and a network interface 666 via interface 624 and/or 604, smart TV 676, consumer electronics 677, etc.

In one embodiment, mass storage device 662 includes, but is not limited to, a solid state drive, a hard disk drive, a universal serial bus flash memory drive, or any other form of computer data storage medium. In one embodiment, network interface 666 is implemented by any type of well-known network interface standard including, but not limited to, an Ethernet interface, a universal serial bus (USB) interface, a Peripheral Component Interconnect (PCI) Express interface, a wireless interface and/or any other suitable type of interface. In one embodiment, the wireless interface operates in accordance with, but is not limited to, the IEEE 802.11 standard and its related family. Home Plug AV (HPAV), Ultra Wide Band (UWB). Bluetooth. WiMax. or any form of wireless communication protocol.

While the modules shown in FIG. 6 are depicted as separate blocks within the system 600, the functions performed by some of these blocks may be integrated within a single semiconductor circuit or may be implemented using two or more separate integrated circuits. For example, although cache memory 616 is depicted as a separate block within processor 610, cache memory 616 (or selected aspects of 616) can be incorporated into processor core 612.

FIG. 7 is a flow diagram of a method 700 of making a surface wave launcher. At 705, a multi-layer PCB is formed using a plurality of board layers. The board layers or panels may include layers made of prepeg. The layers also include a conductive metal such as copper or aluminum. In certain embodiments, the PCB is formed using 2.5D process technology. The board layers include a top board layer, a bottom board layer, and one or more intermediate board layers arranged between the top board layer and bottom board layer. At least a portion of the one or more intermediate layers include a cut out area.

At 710, the plurality of intermediate board layers are stacked with the cut out areas aligned to form a cavity in a side of the multi-layer PCB. In some embodiments two intermediate layers include the cut out area to form the cavity.

At 715, a surface wave launcher for a single-wire transmission line is formed in the at least one intermediate layer below the top surface of the PCB and above the bottom of the PCB. In some embodiments, the launcher is formed by coating the cavity in the intermediate layers with a layer of metal (e.g., copper). In some embodiments, the cavity is coated with graphite and the cavity is plated with the metal layer using the graphite as an electrode in an electroplating process.

In some embodiments, the method 700 includes arranging a launcher die on the board layer below the board layers with the cut area. The launcher die is placed at the position of the cut out area, and the board layers with the cut out area are stacked above the launcher die board layer with the cut out area arranged around the launcher die. The stacked board layers are clamped and heated to the melting pint of the prepeg to form the multi-layer PCB. At this point the PCB is formed and the launcher die is still in the cavity formed by the cut areas. If the launcher die is coated with graphite, it facilitates removal of the launcher die from the cavity and also serves to coat the cavity with graphite if electroplating is used to metalize the cavity. If graphite is not needed for the metallization of the cavity, the launcher die may be coated with a different lubricant to aid in die removal.

The launcher die can also serve to form the desired shape of the cavity. Because the board layers are heated to the melting point, the cavity forms around the launcher die adopting the contours of the launcher die. For example, if the launcher die has a bell shape, a bell shaped cavity is formed. The launcher die may be precision machined to the desired shape. The cavity will form to the die shape and coating the cavity with metal will form a launcher in the desired shape.

The launcher can be formed to contact a feed conductor of the PCB connected to the launcher end. The feed conductor can include one or more conductive traces pre-formed in the PCB on one or more of the intermediate board layers with the cut out area. In certain embodiments, the feed conductor is formed when two of the board layers are joined together. The SWC interconnection can be completed by connecting a single-wire transmission line to the launcher.

The launcher is embedded in the PCB. The launcher is monolithic and does not require additional parts. Making the launcher does not require machining of any parts except the launcher die, which may be formed using precision machining if desired, and the launcher die may be reused. The result is a launcher that is low cast and the manufacturing process is scalable to high volume. The SWC interconnection formed by the launcher may reduce PCB board in count which may further reduce cost.

### ADDITIONAL DESCRIPTION AND EXAMPLES

Example 1 includes subject matter such as an apparatus comprising a multi-layer printed circuit board (PCB) including a plurality of board layers arranged between a top surface of the PCB and a bottom surface of the PCB; and a surface wave launcher for a single-wire transmission line arranged below the top surface of the PCB and above the bottom surface of the PCB.

In Example 2, the subject matter of Example 1 optionally includes the plurality of board layers including a top board layer and a bottom board layer, and the launcher is arranged near an edge of the PCB below the top board layer and above the bottom board layer.

In Example 3, the subject matter of one or both of Examples 1 and 2 optionally includes a launcher that includes a sidewall formed on a sidewall of at least one board layer of the plurality of board layers.

In Example 4, the subject matter of one or any combination of Examples 1-3 optionally includes a launcher that includes a sidewall formed on multiple sidewalls of multiple board layers of the plurality of board layers.

In Example 5, the subject matter of one or any combination of Examples 1-4 optionally includes a launcher that includes a single metal layer formed on the multiple sidewalls of the multiple board layers, a bottom surface of a second board layer, and a top surface of a third board layer.

In Example 6, the subject matter of one or any combination of Examples 1-5 optionally includes a launcher that includes a launcher opening near the edge of the PCB and a launcher end opposite the launcher opening, wherein the launcher opening is wider than the launcher end.

In Example 7, the subject matter of Example 6 optionally includes a single-wire transmission line operatively coupled to the launcher at launcher end opening.

In Example 8, the subject matter of one or any combination of Examples 1-7 optionally includes a launcher having a bell shape.

In Example 9, the subject matter of one or any combination of Examples 1-7 optionally includes a launcher having a horn shape.

Example 10 includes subject matter (such as a method of making a printed circuit board assembly), or can optionally be combined with one or any combination of Examples 1-9 to include such subject matter, comprising forming a multi-layer printed circuit board (PCB) from a plurality of board layers that include a top board layer, a bottom board layer, and at least one intermediate board layer arranged between the top board layer and bottom board layer; and forming a launcher for a single-wire transmission line in the at least one intermediate layer below the top board layer and above the bottom board layer.

In Example 11, the subject matter of Example 10 optionally includes at least one intermediate board layer including a plurality of intermediate board layers each having a cut out area and wherein the forming a launcher includes: forming a cavity in a side of the multi-layer PCB by stacking the plurality of intermediate board layers with the cut out areas aligned to form the cavity; and plating the cavity with a metal layer.

In Example 12, the subject matter if Example 11 optionally includes arranging a launcher die on a board layer at the position of the cut out areas of the intermediate board layers and stacking the intermediate board layers above the launcher die board layer with the cut out areas arranged around the launcher die; stacking the top board layer above the intermediate board layers; laminating the plurality of board layers into the multi-layer PCB; and removing the launcher die from the multi-layer PCB.

In Example 13, the subject matter of Example 12 optionally includes coating the launcher die with graphite prior to stacking the board layers, and wherein plating the cavity with a metal layer includes removing the launcher die and electroplating the cavity with the metal layer using graphite remaining in the cavity as an electrode in the electroplating.

In Example 14, the subject matter of one or any combination of Examples 11-13 optionally includes coating the cavity with graphite and electroplating the cavity with the metal layer using the graphite as an electrode in the electroplating.

In Example 15, the subject matter of one or any combination of Examples 11-14 optionally includes forming a bell shaped cavity in the side of the multi-layer PCB.

In Example 16, the subject matter of one or any combination of Examples 10-15 optionally includes connecting a single-wire transmission line to the launcher.

Example 17 includes subject matter (such as a system), or can optionally be combined with one or any combination of Examples 1-16 to include such subject matter, comprising a multi-layer printed circuit board (PCB) including a plurality of board layers arranged between a top surface of the PCB and a bottom surface of the PCB; a feed conductor formed in the PCB; a surface wave launcher operatively coupled to the feed conductor and arranged below the top surface of the PCB and above the bottom surface of the PCB; and a single-wire transmission line operatively coupled to the surface wave launcher.

In Example 18, the subject matter of Example 17 optionally includes a plurality of board layers that includes a top board layer and a bottom board layer, and the launcher is arranged near an edge of the PCB below the top board layer and above the bottom board layer.

In Example 19, the subject matter of one or both of Examples 17 and 18 optionally includes a launcher that includes a single metal layer including a bottom layer formed on a top surface of a first board layer, a top layer formed on a bottom surface of a second board layer, and a sidewall formed on multiple sidewalls of multiple board layers of the plurality of board layers.

In Example 20, the subject matter of one or any combination of Examples 17-19 optionally includes a processor operatively coupled to the feed conductor.

These non-limiting examples can be combined in any permutation or combination.

The Abstract is provided to allow the reader to ascertain the nature and gist of the technical disclosure. It is submitted with the understanding that it will not be used to limit or interpret the scope or meaning of the claims. The following claims are hereby incorporated into the detailed description, with each claim standing on its own as a separate embodiment.

What is claimed is:

1. An apparatus comprises:
a multi-layer printed circuit board (PCB) including a plurality of board layers arranged between a top surface of the PCB and a bottom surface of the PCB; and
a surface wave launcher for a single-wire transmission line arranged below the top surface of the PCB and above the bottom surface of the PCB.

2. The apparatus of claim 1, wherein the plurality of board layers includes a top board layer and a bottom board layer, and the launcher is arranged near an edge of the PCB below the top board layer and above the bottom board layer.

3. The apparatus of claim 1, wherein the launcher includes a sidewall formed on a sidewall of at least one board layer of the plurality of board layers.

4. The apparatus of claim 1, wherein the launcher includes a sidewall formed on multiple sidewalls of multiple board layers of the plurality of board layers.

5. The apparatus of claim 4, wherein the launcher includes a single metal layer formed on the multiple sidewalls of the multiple board layers, a bottom surface of a second board layer, and a top surface of a third board layer.

6. The apparatus of claim 1, wherein the launcher includes a launcher opening near the edge of the PCB and a launcher end opposite the launcher opening, wherein the launcher opening is wider than the launcher end.

7. The apparatus of claim 6, wherein the launcher end includes a launcher end opening, and wherein the apparatus further includes a single-wire transmission line operatively coupled to the launcher at launcher end opening.

8. The apparatus of claim 1, wherein the launcher has a bell shape.

9. The apparatus of claim 1, wherein the launcher has a horn shape.

10. A method comprising:
forming a multi-layer printed circuit board (PCB) from a plurality of board layers that include a top board layer, a bottom board layer, and at least one intermediate board layer arranged between the top board layer and bottom board layer; and
forming a launcher for a single-wire transmission line in the at least one intermediate layer below the top board layer and above the bottom board layer.

11. The method of claim 10, wherein the at least one intermediate board layer includes a plurality of intermediate board layers each having a cut out area and wherein the forming a launcher includes:
forming a cavity in a side of the multi-layer PCB by stacking the plurality of intermediate board layers with the cut out areas aligned to form the cavity; and
plating the cavity with a metal layer.

12. The method of claim 11, wherein the forming a cavity includes:
arranging a launcher die on a board layer at the position of the cut out areas of the intermediate board layers and stacking the intermediate board layers above the launcher die board layer with the cut out areas arranged around the launcher die;
stacking the top board layer above the intermediate board layers;
laminating the plurality of board layers into the multi-layer PCB; and
removing the launcher die from the multi-layer PCB.

13. The method of claim 12, including coating the launcher die with graphite prior to stacking the board layers, and wherein plating the cavity with a metal layer includes removing the launcher die and electroplating the cavity with the metal layer using graphite remaining in the cavity as an electrode in the electroplating.

14. The method of claim 11, wherein the plating the cavity with a metal layer includes coating the cavity with graphite and electroplating the cavity with the metal layer using the graphite as an electrode in the electroplating.

15. The method of claim 11, wherein forming a cavity includes forming a bell shaped cavity in the side of the multi-layer PCB.

16. The method of claim 10, including connecting a single-wire transmission line to the launcher.

17. A system comprising:
a multi-layer printed circuit board (PCB) including a plurality of board layers arranged between a top surface of the PCB and a bottom surface of the PCB;
a feed conductor formed in the PCB;
a surface wave launcher operatively coupled to the feed conductor and arranged below the top surface of the PCB and above the bottom surface of the PCB; and
a single-wire transmission line operatively coupled to the surface wave launcher.

18. The system of claim 17, wherein the plurality of board layers includes a top board layer and a bottom board layer, and the launcher is arranged near an edge of the PCB below the top board layer and above the bottom board layer.

19. The system of claim 17, wherein the launcher includes a single metal layer including a bottom layer formed on a top surface of a first board layer, a top layer formed on a bottom surface of a second board layer, and a sidewall formed on multiple sidewalls of multiple board layers of the plurality of board layers.

20. The system of claim 17, including a processor operatively coupled to the feed conductor.
